(19) United States
(12) Patent Application Publication
(10) Pub. No.: US 2002/0136073 A1
(43) Pub. Date: Sep. 26, 2002

(54) Integrated circuit devices having a sense amplifier driver disposed between one or more pairs of sense amplifiers and methods of manufacturing same

(76) Inventor: Jae-Yoon Sim, Suwon-city (KR)

Correspondence Address: MYERS BIGEL SIBLEY & SAJOVEC, PO BOX 37428, RALEIGH, NC, 27627, US

(21) Appl. No.: 10/101,287

(22) Filed: Mar. 19, 2002

(30) Foreign Application Priority Data
Mar. 19, 2001 (KR) 01-14113

(51) Int. Cl. G11C 7/02

(52) U.S. Cl. 365/207; 365/208

(57) ABSTRACT

An integrated circuit device includes a pair of bit lines and a pair of sense amplifiers respectively coupled to the pair of bit lines. A sense amplifier driver is coupled to one of the pair of sense amplifiers and is disposed between the pair of sense amplifiers. In other embodiments, an integrated circuit device includes a plurality of sense amplifier pairs including a first group of sense amplifiers and a second group of sense amplifiers. A first plurality of sense amplifier drivers is coupled to the first group of sense amplifiers such that a ratio of the first group of sense amplifiers to the first plurality of sense amplifiers drivers is at least 2:1. A second plurality of sense amplifier drivers is coupled to the second group of sense amplifiers such that a ratio of the second group of sense amplifiers to the second plurality of sense amplifier drivers is at least 2:1.

### RELATED APPLICATION

This application claims the benefit of Korean Patent Application No. 2001 14113, filed Mar. 19, 2001, the disclosure of which is hereby incorporated herein by reference.

### FIELD OF THE INVENTION

The present invention relates generally to integrated circuit devices and methods of operating same and, more particularly, to integrated circuit memory devices and methods of operating same.

### BACKGROUND OF THE INVENTION

Bit line sense amplifiers and bit line sense amplifier drivers may be arranged in multiple ways in conventional integrated circuit memory devices. One approach is to associate a plurality of bit line sense amplifiers with a single bit line sense amplifier driver. Another approach is to associate a plurality of bit line sense amplifiers with a plurality of bit line sense amplifier drivers in one-to-one correspondence.

The first approach may allow an increase in layout area to be avoided because one bit line sense amplifier driver is associated with multiple bit line sense amplifiers. Unfortunately, because a single bit line sense amplifier is used to drive multiple bit line sense amplifiers, a load capacitance of the driving signal lines may increase, which may reduce the transfer speed of a drive signal, which, in turn, may reduce the speed of the bit line sense amplifiers in performing a sense operation.

The second approach may allow a reduction in drive signal transfer speed to be avoided because each bit line sense amplifier is associated with its own bit line sense amplifier driver. Unfortunately, because multiple bit line sense amplifiers and multiple bit line sense amplifier drivers maybe arranged in a single region, layout area may increase.

FIG. 1 illustrates an arrangement of memory cell array blocks in a memory cell array of a conventional integrated circuit memory device. Partial memory cell array blocks are arranged in a non-hatch region 10. Bit line sense amplifiers are arranged in a left-hatch region 12. Contact regions between the bit line sense amplifiers are arranged in a right-hatch region 14. Sub word line drivers of two adjacent partial blocks are arranged in a dotted region 16. Control signal generating circuits that control the sub word line drivers are arranged in a horizontal-hatch region 18. A bit line pair BL and BLB is arranged perpendicular to a word line WL and bit line sense amplifier control signal lines SAP and SAN as shown in FIG. 1.

FIG. 2 is a circuit diagram that illustrates a conventional implementation of the left-hatch region 12 and the right-hatch region 14 of FIG. 1. N bit line pairs BL1 and BLB1 through BL1 and BLBn pass through the bit line sense amplifier region 12. A bit line sense amplifier pair is arranged between each of the bit line pairs BL1 and BLB1 through BLn and BLBn. Each of the bit line sense amplifier pairs includes a PMOS bit line sense amplifier 30 comprising PMOS transistors P1 and P2 and an NMOS bit line sense amplifier 32 comprising NMOS transistors N1 and N2.

Each PMOS bit line sense amplifier is connected between a respective bit line pair. For example, a PMOS bit line sense amplifier 30 comprises PMOS transistors P1 and P2, which are connected in series between the bit line pair BL1 and BLB1. The PMOS transistors P1 and P2 include gates, which are connected to the complementary bit line BLBI and the bit line BLI, respectively, and sources, which are connected to a driving signal line SAH. Each NMOS bit line sense amplifier is also connected between a respective bit line pair. For example, a NMOS bit line sense amplifier 32 comprises NMOS transistors N1 and N2, which are connected in series between the bit line pair BL1 and BLB1. The NMOS transistors N1 and N2 include gates, which are connected to the complementary bit line BLB1 and the bit line BL1, respectively, and sources, which are connected to a driving signal line SAL.

The contact region 14 comprises a bit line sense amplifier driver pair that comprises a PMOS driver transistor P3 and an NMOS driver transistor N3. The PMOS transistor P3 includes a gate that is connected to the bit line sense amplifier control signal line SAP, a source that is connected to a power voltage source, and a drain that is connected to a driving signal line SAH. The NMOS transistor N3 includes a gate that is connected to the bit line sense amplifier control signal line SAN, a source that is connected to a reference potential (e.g., ground), and a drain that is connected to a driving signal line SAL.

Operation of the bit line sense amplifiers and the bit line sense amplifier drivers of FIG. 2 will now be described. For a read operation, control signals having a logic “low” level and a logic “high” level are applied to the driving control signal lines SAH and SAL, respectively. For purposes of illustration, it is assumed that data corresponding to a logic “high” level and a logic “low” level having a relatively small potential difference therebetween are applied to the bit line pair BL1 and BLB1, respectively. The PMOS transistor P3 and the NMOS transistor N3 are turned on, so that the power voltage and the reference potential are applied to the driving signal lines SAP and SAN, respectively. The PMOS transistor P1 and the NMOS transistor N2 are turned on, which drives the bit line pair BL1 and BLB1 to the power voltage and reference potential levels, respectively. As a result, the PMOS bit line sense amplifier 30 and NMOS bit line sense amplifier 32 amplify the logic “high” level and logic “low” level on the bit line pair BL1 and BLB1 so as to drive the bit line pair BL1 and BLB1 to the power voltage level and reference potential level, respectively.

The integrated circuit memory device of FIG. 2 may not require an increase in layout area because one bit line sense amplifier driver pair is disposed in contact region 14 and is associated with multiple bit line sense amplifier pairs 30 and 32, which are disposed in region 12. Unfortunately, because a single PMOS transistor P3 drives n PMOS bit line sense amplifiers 30 and one NMOS transistor N3 drives n NMOS bit line sense amplifiers 32, a load capacitance of the driving signal lines SAP and SAN may increase, which may reduce the transfer speed of drive signals thereon.

FIG. 3 is a circuit diagram that illustrates another conventional implementation of the left-hatch region 12 and the right-hatch region 14 of FIG. 1. N bit line pairs BL1 and BLB1 through BLn and BLBn pass through the bit line sense amplifier region 12. A bit line sense amplifier pair is arranged between each of the bit line pairs BL1 and BLB1 through BLn and BLBn. Each of the bit line sense amplifier pairs includes a PMOS bit line sense amplifier 30 comprising PMOS transistors P1 and P2 and an NMOS bit line sense amplifier 32 comprising NMOS transistors N1 and N2. The PMOS bit line sense amplifier 30 and the NMOS bit line sense amplifier 32 have the same configurations as those discussed above with respect to FIG. 2.

In FIG. 3, multiple bit line sense amplifier driver pairs are disposed in region leaving region 14 without any circuitry. The bit line sense amplifier drivers are configured such that each drives one bit line sense amplifier. Each bit line sense amplifier driver pair comprises a PMOS driver transistor P4 and an NMOS driver transistor N4. Each PMOS transistor P4 includes a gate that is connected to the bit line sense amplifier control signal line SAP, a source that is connected to a power voltage source, and a drain that is connected to a driving signal line SAH. Each NMOS transistor N4 includes a gate that is connected to the bit line sense amplifier control signal line SAN, a source that is connected to a reference potential (e.g., ground), and a drain that is connected to a driving signal line SAL. Operation of the bit line sense amplifiers and the bit line sense amplifier drivers of FIG. 3 is similar to that described above with respect to FIG. 2; therefore, a description is omitted.

The integrated circuit memory device of FIG. 3 may allow a reduction in drive signal transfer speed to be avoided because each bit line sense amplifier pair 30, 32 is associated with its own bit line sense amplifier driver pair, comprising PMOS and NMOS bit line sense amplifier driving transistors. As a result, a driving signal may be rapidly transferred to the driving signal lines SAH and SAL, which may result in relatively fast sensing operation of the PMOS and NMOS bit line sense amplifiers 30 and 32. Unfortunately, because the PMOS and NMOS bit line sense amplifier pairs and the PMOS and NMOS bit line sense amplifier driver pairs are arranged in a single region, layout area may increase.

### SUMMARY OF THE INVENTION

According to some embodiments of the present invention, an integrated circuit device comprises a pair of bit lines and a pair of sense amplifiers respectively coupled to the pair of bit lines. A sense amplifier driver is coupled to one of the pair of sense amplifiers and is disposed between the pair of sense amplifiers.

In other embodiments of the present invention, an integrated circuit device comprises a plurality of sense amplifier pairs comprising a first group of sense amplifiers and a second group of sense amplifiers. A first plurality of sense amplifier drivers is coupled to the first group of sense amplifiers such that a ratio of the first group of sense amplifiers to the first plurality of sense amplifiers drivers is at least 2:1. A second plurality of sense amplifier drivers is coupled to the second group of sense amplifiers such that a ratio of the second group of sense amplifiers to the second plurality of sense amplifier drivers is at least 2:1.

In other embodiments of the present invention, respective ones of a plurality of bit lines are coupled to respective ones of the plurality of sense amplifier pairs and the first and second pluralities of sense amplifier drivers are responsive to a common driver control signal.

In still other embodiments of the present invention, one or more of the first group of sense amplifiers comprises a pair of MOS transistors having a first conductivity type and one or more of the second group of sense amplifiers comprises a pair of MOS transistors having a second conductivity type. In addition, one or more of the first plurality of sense amplifier drivers comprises a MOS transistor having the first conductivity type and one or more of the second plurality of sense amplifier drivers comprises a MOS transistor having the first conductivity type.

In still further embodiments of the present invention, the first and second pluralities of sense amplifier drivers are disposed between the first and second groups of sense amplifiers. Respective ones of the first and second pluralities of sense amplifier drivers may be arranged in an alternating sequence between the first and second groups of sense amplifiers.

Because bit line sense amplifier drivers may be disposed in the same region as bit line sense amplifiers, the layout area of an integrated circuit device need not increase, in accordance with embodiments of the present invention. In addition, because one sense amplifier driver may be used to drive two or more sense amplifiers, a driving signal may be rapidly transferred to a driving signal line, which may allow the sense amplifiers to perform relatively fast sensing operations.

Although embodiments of the present invention have been described above primarily with respect to apparatus embodiments, embodiments of methods of manufacturing integrated circuit devices are also provided.

### BRIEF DESCRIPTION OF THE DRAWINGS

Other features of the present invention will be more readily understood from the following detailed description of specific embodiments thereof when read in conjunction with the accompanying drawings, in which:

FIG. 1 is a block diagram that illustrates an arrangement of memory cell array blocks in a memory cell array of a conventional integrated circuit memory device;

FIGS. 2 and 3 are circuit diagrams that illustrate conventional sense amplifier and sense amplifier driver arrangements in an integrated circuit memory device; and

FIG. 4 is a circuit diagram that illustrates arrangements of sense amplifiers and sense amplifier drivers in accordance with embodiments of the present invention.

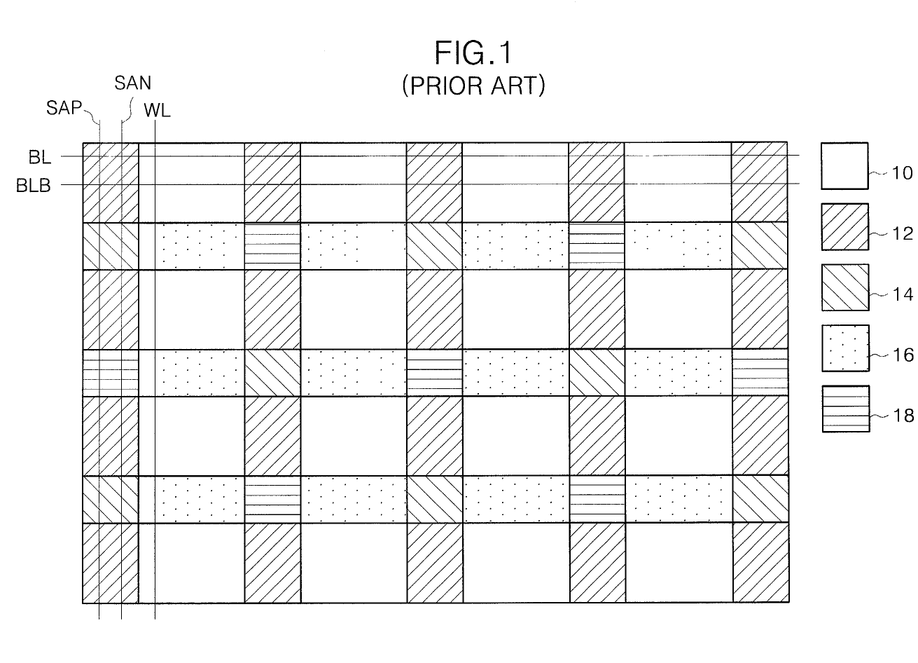

### DETAILED DESCRIPTION OF PREFERRED EMBODIMENTS

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims. Like numbers refer to like elements throughout the description of the figures. It will also be understood that when an element is referred to as being “connected” or “coupled” to another element, it can be directly connected or coupled to the other element or intervening elements may also be present. In contrast, when an element is referred to as being “directly connected” or “directly coupled” to another element, there are no intervening elements present.

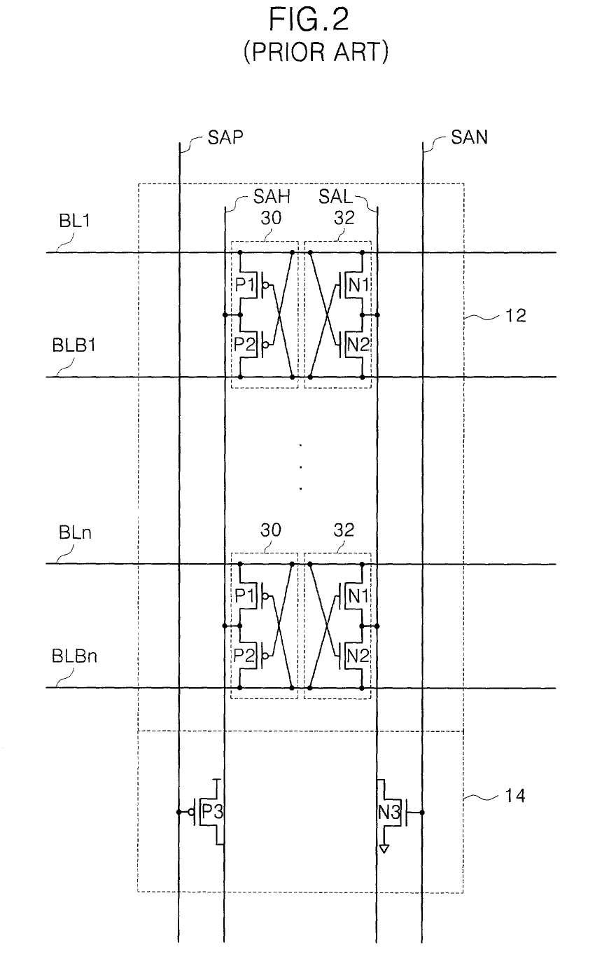

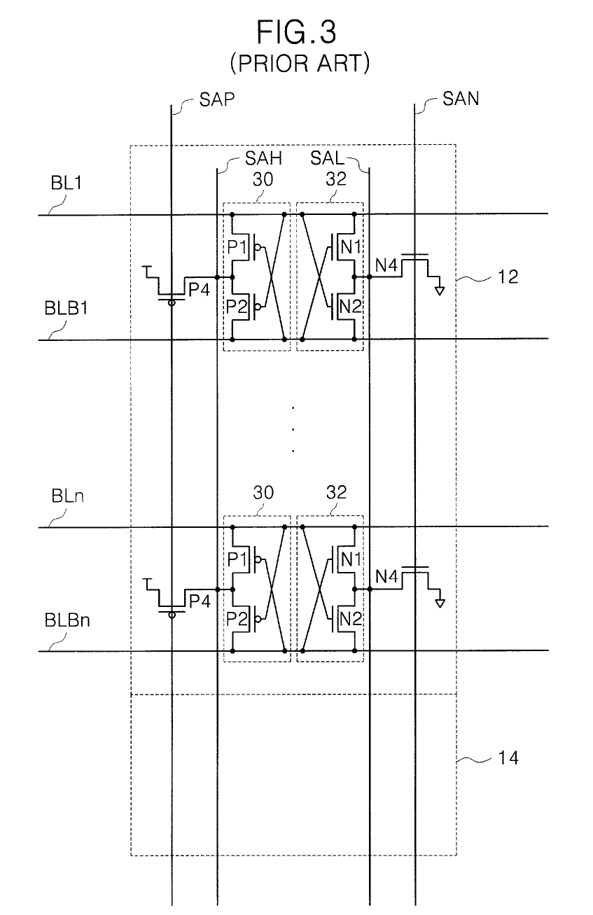

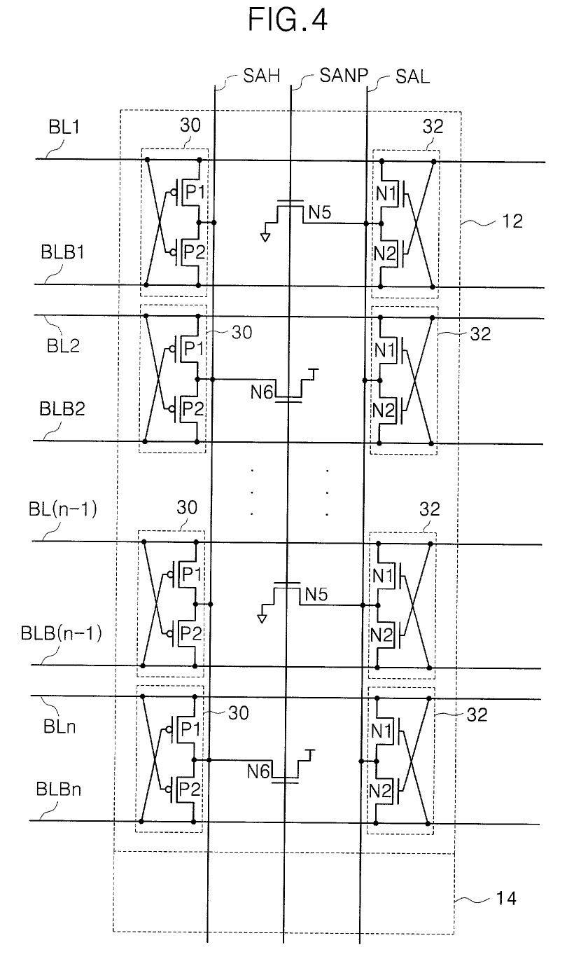

FIG. 4 is a circuit diagram that illustrates an integrated circuit device in accordance with embodiments of the present invention. N bit line pairs BLI and BLB1 through BLn and BLBn pass through the bit line sense amplifier region 12. A bit line sense amplifier pair is arranged between each of the bit line pairs BL1 and BLB1 through BLn and BLBn. Each of the bit line sense amplifier pairs includes a PMOS bit line sense amplifier 30 comprising PMOS transistors P1 and P2 and an NMOS bit line sense amplifier 32 comprising NMOS transistors N1 and N2. The PMOS bit line sense amplifier 30 and the NMOS bit line sense amplifier 32 have the same configurations as those discussed above with respect to FIGS. 2 and 3.

In FIG. 4, multiple bit line sense amplifier drivers are disposed in region 12 leaving region 14 without any circuitry. Each NMOS sense amplifier driver transistor N5 is responsible for driving two NMOS bit line sense amplifiers 32, and each NMOS sense amplifier driver transistor N6 is responsible for driving two PMOS bit line sense amplifiers 30, in accordance with embodiments of the present invention. The NMOS transistors N5 and N6 are alternately arranged between the PMOS bit line sense amplifiers 30 and the NMOS bit line sense amplifiers 32. Each NMOS transistor N5 includes a gate that is connected to a driving control signal line SANP, a source that is connected to a reference potential (e.g., ground), and a drain that is connected to a driving signal line SAL and a common source of the NMOS transistors N1 and N2. Each NMOS transistor N6 includes a gate that is connected to a driving control signal line SANP, a source that is connected to a driving signal line SAH and a common source of the PMOS transistors P1 and P2, and a drain that is connected to a power voltage source.

In response to a logic “high” voltage applied to the driving control signal line SANP, the NMOS transistors N5 and N6 drive the common source of the NMOS transistors N1 and N2 to the reference potential and drive the common source of the PMOS transistors P1 and P2 to the power voltage level, respectively. As shown in FIG. 4, one NMOS transistor N5 drives two NMOS bit line sense amplifiers 32, and one NMOS transistor N6 drives two PMOS bit line sense amplifiers 30. It will be understood, however, that in accordance with other embodiments of the present invention, a single sense amplifier driver transistor may drive two or more bit line sense amplifiers.

As described above, a logic “high” voltage is applied to the driving control signal line SANP as a driving control signal. When the power voltage is applied to the driving control signal line SANP, the common source of the NMOS transistors may be sufficiently driven to the reference potential; however, due to characteristics of the NMOS transistor, the common source of the PMOS transistors P1 and P2 may be driven to a level corresponding to the power voltage level minus as much as a threshold voltage of the NMOS transistor N6. Therefore, to drive the common source of the PMOS transistors P1 and P2 to the power voltage level, a relatively high voltage level may be applied to the driving control signal line SANP to sufficiently boost a gate voltage of the NMOS transistor N6.

Advantageously, because the bit line sense amplifier drivers are disposed in the same region 12 as the bit line sense amplifiers, the layout area of the integrated circuit device need not increase, in accordance with some embodiments of the present invention. In this regard, because the bit line sense amplifier driver transistors N5 and N6 are arranged between the PMOS bit line sense amplifier 30 and the NMOS bit line sense amplifier 32 pairs, a layout area of the region 12 in which the bit line sense amplifiers are arranged need not increase. Because one NMOS transistor N5 drives two or more NMOS bit line sense amplifiers 32 and one NMOS transistor N6 drives two or more PMOS bit line sense amplifiers 30, a driving signal may be rapidly transferred to the driving signal line, which may allow the NMOS and PMOS bit line sense amplifiers 30 and 32 to perform relatively fast sensing operations. An integrated circuit device, according to embodiments of the present invention, may use bit line sense amplifier drivers of the same conductivity type (e.g., NMOS transistors) to drive both PMOS and NMOS bit line sense amplifiers. As a result, a single driving control signal line SANP may be used to control the bit line sense amplifier drivers.

According to some embodiments of the present invention, an integrated circuit device may be configured such that the drivers for the NMOS and PMOS bit line sense amplifiers are alternately arranged, and one NMOS bit line sense amplifier driver drives two or more NMOS bit line sense amplifiers and one NMOS bit line sense amplifier driver drives two or more PMOS bit line sense amplifiers. In further embodiments, multiple drivers for NMOS bit line sense amplifiers may be configured without any drivers for PMOS bit line sense amplifiers disposed therebetween and vice versa.

In concluding the detailed description, it should be noted that many variations and modifications can be made to the preferred embodiments without substantially departing from the principles of the present invention. All such variations and modifications are intended to be included herein within the scope of the present invention, as set forth in the following claims.

I claim:

1. An integrated circuit device, comprising:
a plurality of sense amplifier pairs comprising a first group of sense amplifiers and a second group of sense amplifiers;
a first plurality of sense amplifier drivers coupled to the first group of sense amplifiers such that a ratio of the first group of sense amplifiers to the first plurality of sense amplifier drivers is at least 2:1; and
a second plurality of sense amplifier drivers coupled to the second group of sense amplifiers such that a ratio of the second group of sense amplifiers to the second plurality of sense amplifier drivers is at least 2:1.

2. The integrated circuit device of claim 1, further comprising:
a plurality of bit lines, respective ones of the plurality of bit lines being coupled to respective ones of the plurality of sense amplifier pairs.

3. The integrated circuit device of claim 1, wherein the first and second pluralities of sense amplifier drivers are responsive to a driver control signal.

4. The integrated circuit device of claim 1, wherein a respective one of the first group of sense amplifiers comprises a pair of MOS transistors having a first conductivity type, a respective one of the second group of sense amplifiers comprises a pair of MOS transistors having a second conductivity type, a respective one of the first plurality of sense amplifier drivers comprises a MOS transistor having the first conductivity type, and a respective one of the second plurality of sense amplifier drivers comprises a MOS transistor having the first conductivity type.

5. The integrated circuit device of claim 4, wherein the respective one of the first group of sense amplifiers comprises a pair of NMOS transistors, the respective one of the second group of sense amplifiers comprises a pair of PMOS transistors, the respective one of the first plurality of sense amplifier drivers comprises an NMOS transistor, and the respective one of the second plurality of sense amplifier drivers comprises an NMOS transistor.

6. The integrated circuit device of claim 1, wherein the first and second pluralities of sense amplifier drivers are disposed between the first and second groups of sense amplifiers.

7. The integrated circuit device of claim 6, wherein respective ones of the first and second pluralities of sense amplifier drivers are arranged in an alternating sequence between the first and second groups of sense amplifiers.

8. An integrated circuit device, comprising:
a plurality of sense amplifier pairs comprising a first group of sense amplifiers and a second group of sense amplifiers;
a first plurality of sense amplifier drivers coupled to the first group of sense amplifiers and disposed between the first and second groups of sense amplifiers; and
a second plurality of sense amplifier drivers coupled to the second group of sense amplifiers and disposed between the first and second groups of sense amplifiers.

9. The integrated circuit device of claim 8, further comprising:
a plurality of bit lines, respective ones of the plurality of bit lines being coupled to respective ones of the plurality of sense amplifier pairs.

10. The integrated circuit device of claim 8, wherein the first and second pluralities of sense amplifier drivers are responsive to a driver control signal.

11. The integrated circuit device of claim 8, wherein respective ones of the first and second pluralities of sense amplifier drivers are arranged in an alternating sequence between the first and second groups of sense amplifiers.

12. An integrated circuit device, comprising:
a pair of bit lines;
a pair of sense amplifiers respectively coupled to the pair of bit lines; and
a sense amplifier driver coupled to one of the pair of sense amplifiers and disposed between the pair of sense amplifiers.

13. A method of manufacturing an integrated circuit device, comprising:
providing a plurality of sense amplifier pairs comprising a first group of sense amplifiers and a second group of sense amplifiers;
arranging a first plurality of sense amplifier drivers between the first and second groups of sense amplifiers such that the first plurality of sense amplifier drivers are coupled to the first group of sense amplifiers; and
arranging a second plurality of sense amplifier drivers between the first and second groups of sense amplifiers such that the second plurality of sense amplifier drivers are coupled to the second group of sense amplifiers.

14. The method of claim 8, wherein arranging the first plurality of sense amplifier drivers and arranging the second plurality of sense amplifier drivers comprises:
arranging the first and second pluralities of sense amplifier drivers in an alternating sequence between the first and second groups of sense amplifiers.

15. A method of operating an integrated circuit device, comprising:
coupling at least one of a plurality of sense amplifiers to a first potential using at least one of a plurality of sense amplifier drivers; and
coupling at least another one of the plurality of sense amplifiers to a second potential, different from the first potential, using at least another one of the plurality of sense amplifier drivers, the plurality of sense amplifier drivers being responsive to a common control signal.
